(19) United States
(12) Patent Application Publication
(10) Pub. No.: US 2026/0038749 A1
(43) Pub. Date: Feb. 5, 2026

(54) THERMAL-MECHANICAL FRAMEWORK FOR SOLID-STATE CIRCUIT BREAKERS

(71) Applicant: Amber Semiconductor, Inc., Dublin, CA (US)

(72) Inventors: Mark Telefus, Orinda, CA (US); Reddy Anumula, San Diego, CA (US); Mark Sires, Santa Cruz, CA (US)

(21) Appl. No.: 19/099,839

(22) PCT Filed: Aug. 29, 2023
(86) PCT No.: PCT/US2023/031418

§ 371 Date: Jan. 30, 2025

Related U.S. Application Data
(60) Provisional application No. 63/402,058, filed on Aug. 29, 2022.

(51) Int. Cl. H01H 9/52; H05K 7/20

(52) U.S. Cl. CPC H01H 9/52; H05K 7/20409

(57) ABSTRACT

Thermal management structures and techniques are provided for cooling solid-state circuit breakers. For example, a circuit breaker comprises an integrated heat sink which is configured to absorb and dissipate heat from electronic components of the circuit breaker using a combination of conduction and convection.

### CROSS-REFERENCE TO RELATED APPLICATION

This application claims priority to U.S. Provisional Patent Application Ser. No. 63/402,058, filed on Aug. 29, 2022, the disclosure of which is incorporated herein by reference.

### BACKGROUND

This disclosure relates generally to thermal management techniques for circuit breakers and, in particular, thermal management of solid-state circuit breakers. Electrical circuit breakers are essential components in electric power distribution systems. For example, circuit breakers are typically disposed in a power distribution panel (e.g., circuit breaker panel) which distributes and feeds utility power to a plurality of downstream branch circuits within a given building or home structure. Each circuit breaker is connected between the utility power supply feed and a corresponding one of the branch circuits to protect the branch circuit conductors and electrical loads on the branch circuit. Conventional circuit breakers include electromechanical circuit breakers which have a mechanical switch that can be manually opened and closed, or automatically tripped by operation of (i) an electromagnetic actuator (e.g., solenoid) in response to large surges in current (short-circuits) and (ii) a thermal-mechanical actuator (e.g., bimetallic element) in response to less extreme but longer-term over-current conditions. Due to the electromechanical construction, conventional electromechanical circuit breakers can be slow to react to fault conditions, and typically require at least several milliseconds to isolate a fault condition, which is undesirable since such delay raises the risk of hazardous fire, damage to electrical equipment, and arc-flashes, which can occur at the short-circuit location when a bolted fault is not isolated quickly enough.

On the other hand, solid-state circuit breakers can implement solid-state alternating current (AC) switches to interrupt AC current, and associated electronics to control operation of the solid-state AC switches. Compared to conventional electromechanical circuit breakers, solid-state circuit breakers provide significantly faster reaction times (e.g., on the order of hundreds of microseconds) to isolate fault conditions such as short-circuit conditions, and over-current conditions. However, solid-state circuit breakers can generate a significant amount of heat as a result of the operation of high-voltage solid-state AC switches and associated control electronics, which can cause a relatively large amount of thermal stress to the solid-state components. Such thermal stress can damage or otherwise reduce the useful lifetime of the solid-state components. Accordingly, an effective thermal design of a solid-state circuit breaker is desirable to avoid overheating and thermal stress on the solid-state electronic components.

### SUMMARY

Exemplary embodiments of the disclosure include thermal management structures and techniques for cooling solid-state circuit breakers. For example, an exemplary embodiment includes a circuit breaker which comprises an integrated heat sink that is configured to absorb and dissipate heat from electronic components of the circuit breaker using a combination of conduction and convection.

Another exemplary embodiment includes a circuit breaker which comprises an electronic assembly and an integrated heat sink. The electronic assembly comprises electronic components. The integrated heat sink is configured to absorb and dissipate heat from the electronic components of the electronic assembly. The integrated heat sink comprises a first cooling plate and a second cooling plate. At least a portion of the electronic assembly is disposed between the first and second cooling plates to cause the first and second cooling plates to absorb heat generated by the electronic components through conduction.

Another exemplary embodiment includes a DIN rail mount circuit breaker comprising an integrated heat sink which is configured to absorb and dissipate heat from electronic components of the DIN rail mount circuit breaker. The integrated heat sink comprises a first extended portion which extends out from a plastic housing of the DIN rail mount circuit breaker and which is configured make thermal contact to a DIN rail mount to dissipate heat from the integrated heat sink to the DIN rail mount.

In another exemplary embodiment, which may be combined with one or more of the embodiments of the preceding paragraphs, the integrated heat sink is disposed within a plastic housing of the circuit breaker, and the integrated heat sink comprises at least one extended portion which extends out from the plastic housing and is configured to dissipate heat to an external environment.

In another exemplary embodiment, which may be combined with one or more of the embodiments of the preceding paragraphs, the at least one extended portion comprises an external cooling fin structure that is configured to dissipate heat to external ambient air through convective heat transfer.

In another exemplary embodiment, which may be combined with one or more of the embodiments of the preceding paragraphs, the at least one extended portion comprises a rail contact structure which is configured to couple to a circuit breaker mounting rail and dissipate heat to the circuit breaker mounting rail through conductive heat transfer.

In another exemplary embodiment, which may be combined with one or more of the embodiments of the preceding paragraphs, the integrated heat sink comprises a unitary molded element formed of a thermally conductive material, such as a unitary molded aluminum structure.

In another exemplary embodiment, which may be combined with one or more of the embodiments of the preceding paragraphs, the circuit breaker comprises an electronic assembly which comprises a first substrate and a second substrate. The electronic components comprise (i) a plurality of solid-state switch devices mounted on the first substrate, and configured to implement a solid-state AC switch, and (ii) integrated circuit (IC) chips mounted on the second substrate, and configured to implement control circuitry for controlling operation of the solid-state AC switch. The integrated heat sink comprises a first cooling plate and a second cooling plate. The first and second substrates of the electronic assembly are disposed between the first and second cooling plates. The first and second cooling plates are configured to absorb heat, which is generated by the electronic components, through conduction.

In another exemplary embodiment, which may be combined with one or more of the embodiments of the preceding paragraphs, the plurality of solid-state switch devices are mounted on a frontside surface of the first substrate. The IC chips are mounted on a frontside surface of the second substrate. The first cooling plate is thermally coupled to a backside surface of the first substrate, opposite the frontside surface of the first substrate. The second cooling plate is thermally coupled to backside surfaces of the IC chips.

In another exemplary embodiment, which may be combined with one or more of the embodiments of the preceding paragraphs, the electronic assembly comprises a first wire connector terminal coupled to the first substrate, and a second wire connector terminal coupled to the first substrate. The first and second wire connector terminals are configured to absorb heat from the first substrate through conduction, and dissipate heat to an external environment through conduction of the heat to electrical wiring connected to the first and second wire connector terminals.

In another exemplary embodiment, which may be combined with one or more of the embodiments of the preceding paragraphs, the first and second cooling plates are configured to absorb heat generated by the electronic components and create a temperature differential between the first and second cooling plates which causes a convective air flow within a housing of the circuit breaker to circulate heated air to other components of the integrated heat sink and cause convective heat transfer from the heated air to the other components of the integrated heat sink.

Other embodiments will be described in the following detailed description of exemplary embodiments, which is to be read in conjunction with the accompanying figures.

### BRIEF DESCRIPTION OF THE DRAWINGS

FIGS. 1A, 1B, 1C, 1D, 1E, and IF are schematic perspective views of a solid-state circuit breaker which comprises an integrated heat sink, according to an exemplary embodiment of the disclosure.

FIGS. 2A, 2B, and 2C are schematic perspective views of a solid-state circuit breaker coupled to a mounting rail, according to an exemplary embodiment of the disclosure.

FIG. 3 schematically illustrates electronic components of an intelligent solid-state circuit breaker, according to an exemplary embodiment of the disclosure.

FIG. 4 schematically illustrates an embodiment of a solid-state AC switch, which can be implemented in a solid-state circuit breaker, according to an exemplary embodiment of the disclosure.

FIG. 5 schematically illustrates an embodiment of a solid-state AC switch, which can be implemented in a solid-state circuit breaker, according to another exemplary embodiment of the disclosure.

### DETAILED DESCRIPTION

Embodiments of the disclosure will now be described in further detail with regard solid-state circuit breakers which comprise integrated heat sinks that are configured to absorb and dissipate heat from electronic components of the solid-state circuit breakers using a combination of conduction and convection. Exemplary embodiments of the disclosure include techniques for thermal management of solid-state circuit breakers which comprise, e.g., high-power solid-state switch devices to implement a solid-state AC switch, and control electronics to control operation of the solid-state AC switch and implement intelligent circuit breaker functionality.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) devices, field programmable gate array (FPGA) devices, etc.), processing devices (e.g., central processing unit (CPU) devices, graphical processing unit (GPU) devices, microcontroller devices, etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

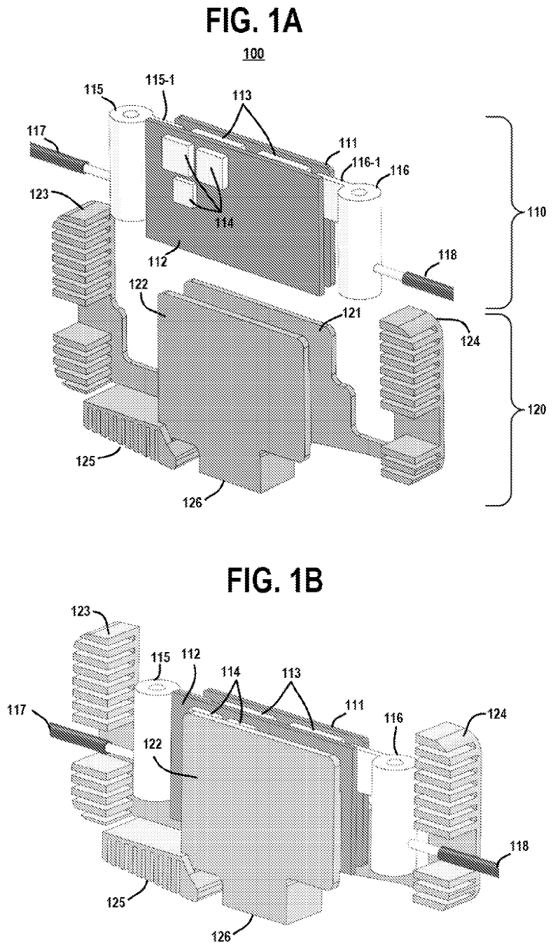

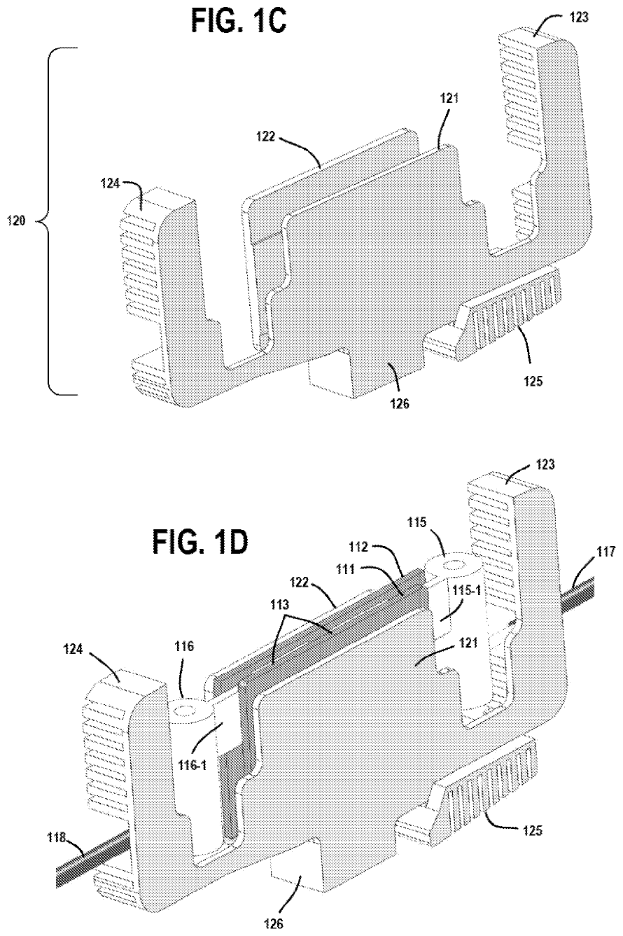

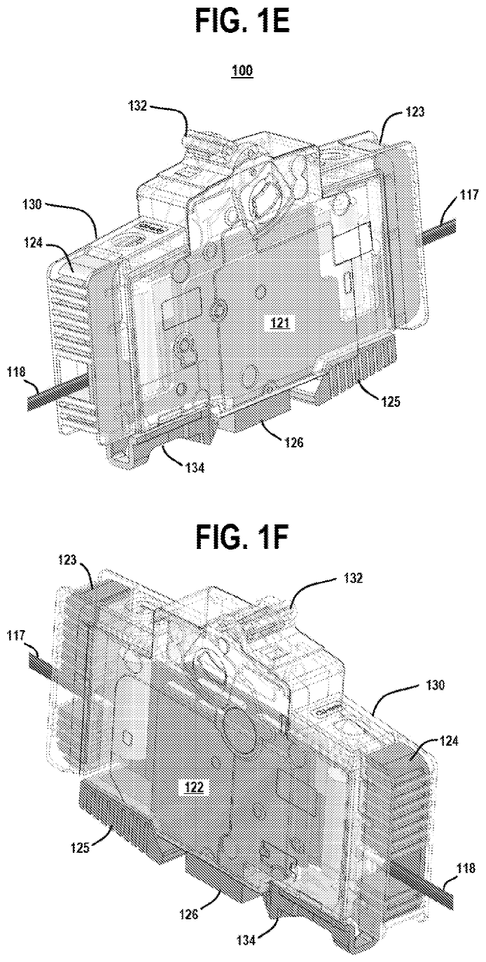

FIGS. 1A, 1B, 1C, 1D, 1E, and IF are schematic perspective views of a solid-state circuit breaker which comprises an integrated heat sink, according to an exemplary embodiment of the disclosure. In particular, FIGS. 1A-1F collectively illustrate a solid-state circuit breaker 100 according to an exemplary embodiment of the disclosure, wherein the solid-state circuit breaker 100 comprises an electronic assembly 110, an integrated heat sink element 120, and a housing 130 (e.g., plastic outer claim shell casing). FIG. 1A is an exploded view which separately shows the electronic assembly 110 and the integrated heat sink element 120, while FIG. 1B is a perspective view of an assembled configuration of the electronic assembly 110 and the integrated heat sink element 120. FIG. 1C is another perspective view of the integrated heat sink element 120 alone, and FIG. 1D is another perspective view of the assembled configuration of the electronic assembly 110 and the integrated heat sink element 120. Finally, FIGS. 1E and 1F show different perspective views of the solid-state circuit breaker 100, wherein the housing 130 (e.g., plastic outer clam shell casing) is shown in phantom. In addition, FIGS. 1E and 1F illustrate other components of the solid-state circuit breaker 100 including, but not limited to a manual switch 132, and a mounting clip 134. The manual switch 132 allows a user to manually switch the solid-state circuit breaker 100 in an ON state, or an OFF state, or otherwise manually reset the solid-state circuit breaker 100 after the breaker is automatically tripped in response to a detected fault condition (e.g., short circuit). As explained in further detail below, the mounting clip 134 is configured for securely mounting the solid-state circuit breaker 100 to, e.g., a mounting rail.

As collectively shown in, e.g., FIGS. 1A, 1B, and 1D, the electronic assembly 110 comprises a first substrate 111, a second substrate 112, a plurality of solid-state switch devices 113, a plurality of electronic integrated circuit (IC) chips 114, a first wire terminal connector 115, and a second wire terminal connector 116. In some embodiments, the first substrate 111 and the second substrate 112 comprise printed circuit boards (PCBs) on which the various chips and electronic devices are mounted. In particular, the solid-state switch devices 113 are mounted on a frontside surface of the first substrate 111, and the electronic IC chips 114 are mounted on the frontside surface of second substrate 112.

In some embodiments, the solid-state switch devices 113 comprise two or more high power solid-state switch devices, which are operatively connected to implement a solid-state bidirectional switch. In some embodiments, the solid-state switch devices 113 comprise power metal-oxide-semiconductor field-effect transistor (MOSFET) devices (e.g., individual MOSFET chips), although other types of solid-state switch devices may be implemented, as discussed in further detail below. The electronic IC chips 114 collectively comprise control circuitry for controlling the operation of the solid-state AC switch and performing other control functions for implementing an intelligent solid-state circuit breaker. For example, the electronic IC chips 114 comprise one or more microprocessors, switch control circuitry, sensor circuitry, and other circuitry for implementing intelligent functions of the solid-state circuit breaker 100.

The first wire terminal connector 115 and the second wire terminal connector 116 are configured to enable the connection of electrical wiring to the solid-state circuit breaker 100. For example, as shown in FIGS. 1A, 1B, and 1D, a first wire 117 is connected to the first wire terminal connector 115, and a second wire 118 is connected to the second wire terminal connector 116. In an exemplary embodiment, the first wire 117 can be a line hot wire (which is coupled to line phase of utility power), and the second wire 118 can be a load hot wire that feeds AC power to a branch circuit or load device. For ease of illustration, a neutral wire connection to the solid-state circuit breaker 100 is not shown in the figures, although in practice a neutral pigtail wire would be coupled to a neutral node of the circuitry (electronic IC chips 114) mounted on the frontside surface of second substrate 112. As further shown, the first wire terminal connector 115 comprises an extended connection tab 115-1 that is connected to the first substrate 111 to provide an electrical connection to a line side node of the solid-state AC switch formed by the solid-state switch devices 113, and the second wire terminal connector 116 comprises an extended connection tab 116-1 that is connected to the first substrate 111 to provide an electrical connection to a load side node of the solid-state AC switch formed by the solid-state switch devices 113. As explained in further detail below, the first and second wire terminal connectors 115 and 116, and the first and second wires 117 and 118 connected thereto, provide a mechanism for efficient convective heat transfer and conductive heat transfer for cooling the electronic assembly 110.

As collectively shown in, e.g., FIGS. 1A, 1B, 1C, and 1D, the integrated heat sink 120 comprises a first plate 121, a second plate 122 (alternatively referred to herein as first and second cooling plates), a first cooling fin structure 123, a second cooling fin structure 124, a third cooling fin structure 125, and a rail contact structure 126 (alternatively, base structure 126). In some embodiments, the integrated heat sink 120 comprises a unitary molded element formed of any suitable thermally conductive material such as a metallic material. For example, in an exemplary embodiment, the integrated heat sink 120 comprises a molded aluminum structure. The integrated heat sink 120 can be constructed of other suitable materials or alloys with sufficient thermal conductivity for the given application. The integrated heat sink 120 comprises a thermal conductive mechanical architecture that is configured to absorb and dissipate heat from electronic components of the solid-state circuit breaker 100 using a combination of conduction and convection. In particular, the integrated heat sink 120 is configured to absorb and disperse heat away from the electronic assembly 110 using a combination of conduction and convection. In addition, the assembled configuration of the electronic assembly 110 and the integrated heat sink 120 comprises a thermal conductive mechanical architecture that is configured to absorb and dissipate heat from electronic components of the solid-state circuit breaker 100 using a combination of conduction and convection. The term “conduction” as used herein generally refers to the transfer of heat (flow of thermal energy) from one solid to another solid. The term “convection” (or convective heat transfer) as used herein generally refers to the transfer of heat from one point to another due to the movement of gas (e.g., air).

As shown, for example, in FIGS. 1B and 1D, in an exemplary assembled configuration, the first and second substrates 111 and 112 of the electronic assembly 110 are disposed (sandwiched) between the first and second cooling plates 121 and 122, with the first wire terminal connector 115 disposed adjacent to the first cooling fin structure 123, and the second wire terminal connector 116 disposed adjacent to the second cooling fin structure 124. In some embodiments, the first and second wire terminal connectors 115 and 116 comprise elongated metallic structures (e.g., elongated cylindrical shaped structures) that extend adjacent to most or all of the length or height of the first and second cooling fin structures 123 and 124, respectively.

In some embodiments, the first cooling plate 121 is thermally coupled to a backside surface of the first substrate 111 with thermal interface material (TIM) material disposed therebetween to enhance the transfer of heat from the first substrate 111 (which is generated by the high-power solid-state switch devices 113) to the first cooling plate 121. Further, in some embodiments, the second cooling plate 122 is thermally coupled (via a TIM layer) to backside surfaces of the electronic IC chips 114 that are mounted to the second substrate 112. The TIM comprises any material that is suitable for the given application to enhance the heat transfer from one component to another component. In some embodiments, the electronic assembly 110 and the integrated heat sink 120 are physically secured together using screws, and thermally coupled using TIM. As shown in FIGS. 1E and 1F, the electronic assembly 110 and the integrated heat sink 120 are disposed within, and covered by, the housing 130 (e.g., plastic clam shell mold), while the third cooling fin structure 125, and the rail contact structure 126 of the integrated heat sink 120 extend out from the housing 130, and are exposed to the external environment and not covered by the housing 130.

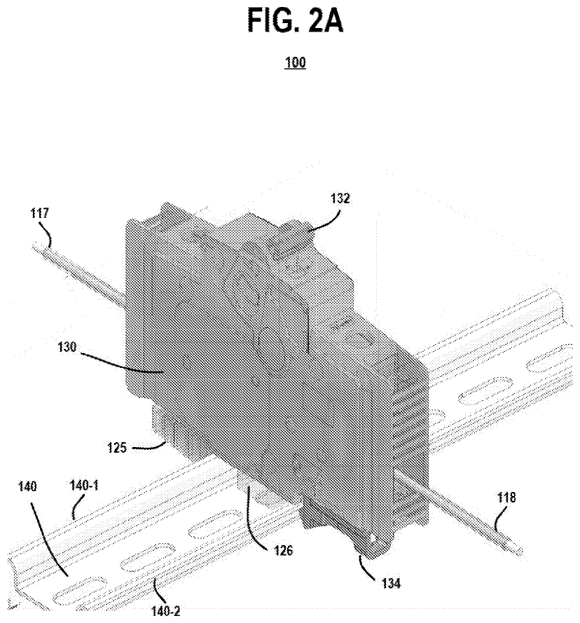

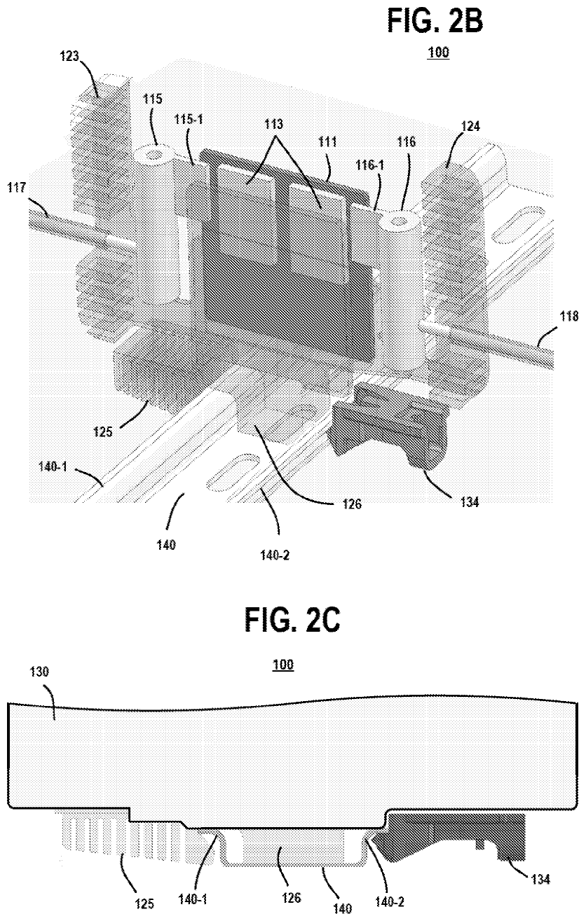

FIGS. 2A, 2B, and 2C are schematic perspective views of the solid-state circuit breaker 100 coupled to a mounting rail 140, according to an exemplary embodiment of the disclosure. In particular, FIGS. 2A-2C illustrate an exemplary embodiment of the solid-state circuit breaker 100 coupled to a mounting rail 140 with the exposed rail contact structure 126 of the integrated heat sink 120 in physical and thermal contact with the mounting rail 140. In an exemplary embodiment, the mounting rail 140 comprises a DIN rail mount and, in particular, a top hat section (TH) type DIN rail mount having a hat-shaped cross section with a first lip 140-1 and a second lip 140-2. A DIN rail mount is a metal rail of a standard type which is commonly used for mounting circuit breakers and industrial control equipment inside equipment racks. A DIN rail mount is commonly fabricated from cold rolled carbon steel sheet with, e.g., a zinc-plated or chromated bright surface finish. The mounting rail 140 is configured to provide mechanical support for the circuit breaker, and not to conduct electric current.

Further, as collectively shown in FIGS. 2A-2C, when solid-state circuit breaker 100 is mounted to the mounting rail 140, the exposed rail contact structure 126 of the integrated heat sink 120 makes contact to the mounting rail 140 to provide a conductive thermal path from the integrated heat sink 120 to the mounting rail 140, wherein the mounting rail 140 further serves as a heat sink to conduct heat from the solid-state circuit breaker 100. In some embodiments, the solid-state circuit breaker 100 is physically secured to the mounting rail 140 by operation of the third cooling fin structure 125 and the plastic mounting clip 134. In particular, as specifically shown in FIG. 2C, the third cooling fin structure 125 essentially operates as a fixed mounting clip that engages the first lip 140-1 of the mounting rail 140, while the plastic mounting clip 134 (e.g., slidable clip, spring loaded clip, etc.) engages the second lip 140-2 of the mounting rail 140, and the rail contact structure 126 serves as a support base structure (or DIN foot element) that is slightly pressed against the flat bottom portion of the mounting rail 140 between the first and second lips 140-1 and 140-2. In addition, the exposed the third cooling fin structure 125 serves to dissipate heat from the integrated heat sink 120 to the ambient air through convection.

As noted above, the exemplary solid-state circuit breaker 100 with the integrated heat sink 120 and, in particular, the assembled configuration of the electronic assembly 110 and the integrated heat sink 120, provides a thermal-mechanical framework that is configured to absorb and dissipate heat away from the electronic components 113 and 114 of the electronic assembly 110 using a combination of heat transfer mechanisms including conduction and convection. In particular, the thermal-mechanical framework provides multiple modes of conductive heat transfer (via conduction). For example, the first cooling plate 121, which is thermally coupled (via TIM layers) to the backside surface of the first substrate 111, provides means for conductive heat transfer from the first substrate 111 to the integrated heat sink 120 to absorb heat that is generated by the high-power or high-voltage solid-state switch devices 113 mounted on the frontside of the first substrate 111. In this regard, the first substrate 111 essentially serves as a heat spreader which absorbs heat from the solid-state switch devices 113 and transfers the heat to the first cooling plate 121 of the integrated heat sink 120. Further, the second cooling plate 122, which is thermally coupled (via TIM layers) to the backside surfaces of the electronic IC chips 114, provides means for conductive heat transfer from the electronic IC chips 114 to the second cooling plate 122 of the integrated heat sink 120.

Another mode of thermal conduction is provided by a conductive heat transfer from the first substrate 111 to the first and second wire terminal connectors 115 and 116 via the respective connection tabs 115-1 and 116-1, and conductive heat transfer from the first and second wire terminal connectors 115 and 116 to the first and second wires 117 and 118 (e.g., 12-gauge wires). In this configuration, the first and second wires 117 and 118 essentially function as heat exhaust elements to dissipate heat to the external environment.

Further, thermal conduction is provided through conductive heat transfer from the rail contact structure 126 of the integrated heat sink 120 to the mounting rail 140. In particular, heat that is absorbed by the first and second cooling plates 121 and 122, and by the first and second cooling fin structures 123 and 124, can dissipate to the mounting rail 140 through the rail contact structure 126 of the integrated heat sink 120. The mounting rail 140 absorbs heat from the rail contact structure 126 and serves as a heat spreader to dissipate the heat into the external environment (external to the solid-state circuit breaker 100).

Moreover, the thermal-mechanical framework provides multiple modes of convective heat transfer. For example, a natural convective air flow occurs within the interior of the housing 130 of the solid-state circuit breaker 100 as result of the relatively large temperature differential between the large amount of heat generated by the high-power solid-state switch devices 113 and the smaller amount of heat generated by the electronic IC chips 114. In some instances, the amount of heat generated by the high-power solid-state switch devices 113 can be around 8 to 10 times more that the amount of heat generated by electronic IC chips 114. As such, a convective air flow (heated airflow) is generated due to the temperature differential between the first and second cooling plates 121 and 122. The convective air flow within the interior of the housing 130 causes heated air to flow to the first and second wire terminal connectors 115 and 116, and to the first and second cooling fin structures 123 and 124, resulting in a convective heat transfer from the heated air to (i) the first and second wire terminal connectors 115 and 116, and to (ii) the first and second cooling fin structures 123 and 124. In other words, the first and second wire terminal connectors 115 and 116, and the first and second cooling fin structures 123 and 124 absorb heat from the heated air of the convective air flow, wherein the absorbed heat is dissipated to the exterior environment by conduction via the first and second wires 117 and 118, and the rail contact structure 126.

Another mode of convective heat transfer is provided by the externally exposed third cooling fin structure 125 of the integrated heat sink 120. In particular, some heat that is absorbed by the integrated heat sink 120 transfers to the third cooling fin structure 125, wherein a convective heat transfer occurs in which heat from the third cooling fin structure 125 is dissipated to the ambient air external to the housing 130 the solid-state circuit breaker 100.

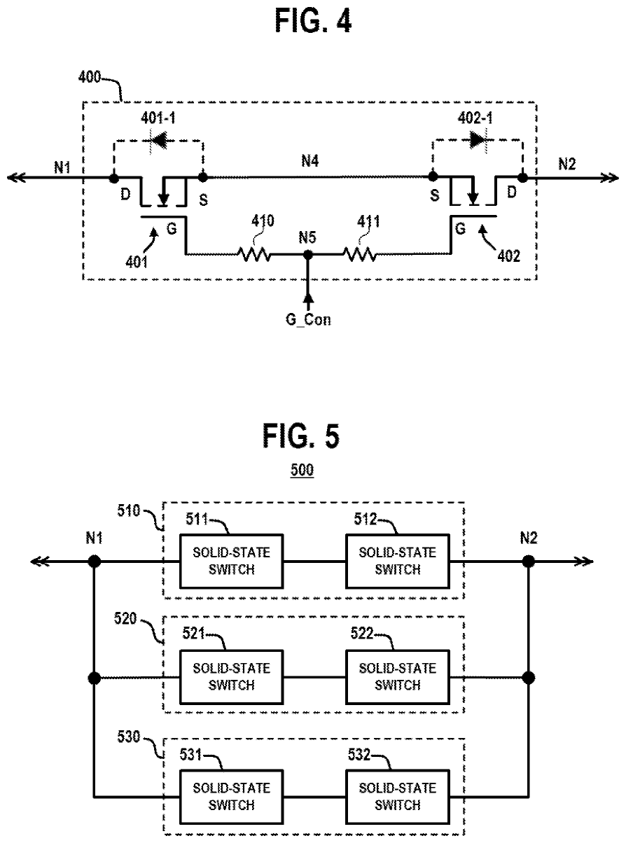

In some embodiments, the integrated heat sink 120 is molded to fit a standard form factor of the circuit breaker housing 130. In addition, the clipping mechanisms provided by the exposed third cooling fin structure 125 of the integrated heat sink 120, and the plastic mounting clip 134 (which is a component of the housing 130) are constructed to have a form factor that is compatible with a standard mounting rail such as a DIN rail mount. In addition, the solid-state circuit breaker 100 can be designed in a same or similar manner for different current ratings (e.g., 10 amperes (A), 20 A, etc.). In this instance, the number of solid-state switch devices 113 can vary depending on the current rating, as discussed in further detail below in conjunction with FIGS. 4 and 5.

It is to be noted that the exemplary embodiments of FIGS. 1A-1F and 2A-2C are merely illustrative embodiments of implementing a DIN rail mount circuit breaker which comprises an integrated heat sink that is configured to absorb and dissipate heat from electronic components of the DIN rail mount circuit breaker, and wherein the integrated heat sink comprises an extended portion which extends out from a plastic housing of the DIN rail mount circuit breaker and which is configured make thermal contact to a DIN rail mount to dissipate heat from the integrated heat sink to the DIN rail mount. However, the same or similar thermal-mechanical structures and techniques can be readily applied for thermal management of solid-state circuit breakers having other types of circuit breaker form factors, and not just DIN circuit breaker form factors.

In addition, while the exemplary embodiments are described in the context of single-pole solid-state circuit breakers, it is to be understood that the same or similar thermal-mechanical structures and techniques can be readily applied for thermal management of solid-state double-pole circuit breakers. Moreover, the same or similar thermal-mechanical structures and techniques can be readily applied for thermal management of hybrid circuit breakers which implement a combination solid-state switches and associated electronics, and a mechanical switch (e.g., air gap switch). Furthermore, while exemplary embodiments are discussed herein in the context of AC circuit breakers, it is to be understood that the same or similar thermal-mechanical structures and techniques can be readily applied for thermal management of solid-state direct current (DC) circuit breakers.

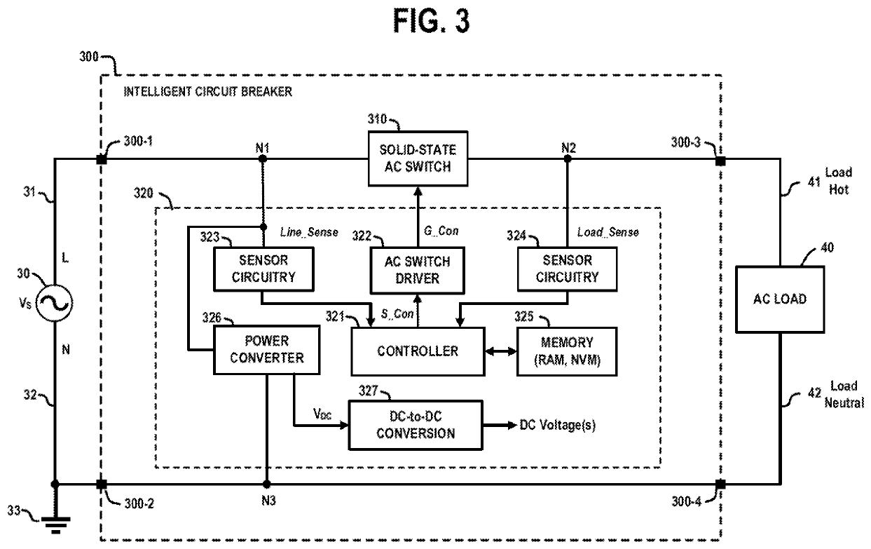

It is to be further understood that the exemplary electronic assembly 110 as shown, for example, in FIG. 1A, is a generic illustration of electronic components 113 and 114 disposed on the first and second substrates 111 and 112, respectively, which is presented to describe exemplary thermal-mechanical structures and techniques for thermal management of solid-state circuit breakers. The types of electronic components 113 and 114 and associated AC switch and control circuit architectures that are implemented will vary depending on, e.g., the intelligent functions supported by the solid-state circuit breaker, the current rating of the solid-state circuit breaker, etc. By way of example, FIG. 3 schematically illustrates electronic components of an intelligent solid-state circuit breaker, according to an exemplary embodiment of the disclosure. In particular, FIG. 3 schematically illustrates an intelligent solid-state circuit breaker 300 which comprises a first power input terminal 300-1, a second power input terminal 300-2, a first load terminal 300-3, a second load terminal 300-4, a solid-state AC switch 310, and an intelligent switch control system 320. The intelligent switch control system 320 comprises various components and circuitry such as a controller 321, AC switch driver circuitry 322, sensor circuitry 323 and 324, one or more memory devices 325, a power converter 326, and DC-to-DC conversion circuitry 327, the functions of which will be explained in detail below. In some embodiments, the solid-state AC switch 310 comprises a bidirectional solid-state switch comprising, e.g., two solid-state switches that are serially connected back-to-back, an exemplary embodiment of which will be described below in conjunction with FIG. 4. The solid-state AC switch 310 is connected to and between a line side node N1 and load side node N2. The intelligent switch control system 320 may comprise a system-on-a-chip (SoC) device or a system-in-package (SIP) device which integrates the various components 321, 322, 323, 324, 325, 326, and 327 (or portions thereof) in a package structure.

The intelligent solid-state circuit breaker 300 is configured to control AC power that is supplied from an AC power source 30 (e.g., AC mains) to an AC load 40. The first and second power input terminals 300-1 and 300-2 are configured to connect the intelligent solid-state circuit breaker 300 to a line phase (L) 31 and a neutral phase (N) 32 of the AC power source 30. The first and second load terminals 300-3 and 300-4 are configured to connect the intelligent solid-state circuit breaker 300 to a load hot line 41 and a load neutral line 42, respectively, which are connected to the AC load 40. The neutral phase (N) 32 of the AC power source 30 is bonded to earth ground 33 (GND). The earth ground 33 is typically connected to a ground bar in a circuit breaker distribution panel, wherein the ground bar is bonded to a neutral bar in the circuit breaker distribution panel. An earth ground connection is made from the ground bar in the circuit breaker distribution panel to an earth ground terminal (not shown) of the intelligent solid-state circuit breaker 300. The earth ground 33 provides an alternative low-resistance path for ground-fault return current to flow in the event of an occurrence of a ground-fault condition detected by the intelligent solid-state circuit breaker 300.

The intelligent switch control system 320 implements control circuitry, control logic and algorithms that are configured to intelligently control various functions and operations of the intelligent solid-state circuit breaker 300. The power converter 326 is configured to generate an output voltage V_{DC}. The power converter 326 is coupled to nodes N1 and N3 to thereby apply the AC power input to the power converter 326. In an exemplary embodiment, the power converter 326 generates an output voltage V_{DC} which is ground referenced to the neutral N (node N3) of the AC power source 30. The output voltage V_{DC} is applied to an input of the DC-to-DC conversion circuitry 327. The DC-to-DC conversion circuitry 327 is configured to convert the voltage V_{DC} into one or more regulated DC voltages that are used as DC supply voltages to operate the components and circuitry of the intelligent switch control system 320.

In some embodiments, the DC-to-DC conversion circuitry 327 comprises one or more DC-DC step-down voltage switching regulator circuits (e.g., Buck switching regulators) which are configured to convert the voltage V_{DC} into or more regulated DC rail voltages with different voltage levels. In some embodiments, the DC-to-DC conversion circuitry 327 is configured to convert the voltage V_{DC} into, e.g., one or more industry standard DC voltages including, but not limited to 12V, 10V, 5V, 3.3V, 2.5V, 2.7V, 1.8V, etc., as needed, depending on the DC supply voltage requirements of the control circuitry of the intelligent switch control system 320, and the AC switch driver circuitry 322.

In some embodiments, the controller 321 is implemented using at least one intelligent, programmable hardware processing device such as a microprocessor, a microcontroller, an ASIC, an FPGA, a CPU, etc., which is configured to execute software routines to generate switch control signals (denoted S (on), which are applied to the AC switch driver circuitry 322 to intelligently control the operation of the solid-state AC switch 310 to perform various functions in response to detection of fault events (e.g., over-current, short-circuit, ground-fault, etc.), depending on the configuration of the intelligent solid-state circuit breaker 300. In some embodiments, the one or more memory devices 325 comprise volatile random-access memory (RAM) and non-volatile memory (NVM), such as Flash memory, to store calibration data, operational data, and executable code for performing various intelligent operations of the intelligent solid-state circuit breaker 300.

In the exemplary embodiment of FIG. 3, the AC switch driver circuitry 322 is configured to generate gate control signals (denoted G_Con) in response to switch control signals S_Con from the controller 321, wherein the gate control signals G_Con are applied to a control terminal of the solid-state AC switch 310 to turn on/off the solid-state AC switch 310. Although not specifically shown in FIG. 3, in a neutral ground-referenced design, some form of isolation circuitry and/or components would be implemented to provide AC-DC isolation and properly drive the solid-state AC switch 310 with gate control signals G_Con generated by the AC switch driver circuitry 322.

In some embodiments, the sensor circuitry 323 comprises voltage detection and/or current detection circuitry to sense a line voltage and/or a line current at node N1 at the line side of the solid-state AC switch 310. Further, in some embodiments, the sensor circuitry 324 comprises voltage detection circuitry and/or current detection circuitry to sense load voltage and/or load current at node N2 at the load side of the solid-state AC switch 310. The configuration and types of sensors used for the sensor circuitry 323 and 324 will vary depending on the application. For example, the line-side sensor circuitry 323 may comprise a voltage phase detector to determine zero-crossings of the AC supply voltage waveform at node N1 and the direction of polarity transition of the AC supply voltage waveform at node N1 (e.g., transition from a positive to a negative half-cycle, or transition from a negative to a positive half-cycle of AC supply voltage waveform Vs). The zero-crossing detections are processed by the controller 321 to determine and control the timing at which the solid-state AC switch 310 is activated and deactivated following a detected zero-voltage crossing of the AC supply voltage waveform at the line sense node N1.

In some embodiments, for intelligent circuit breaker applications, the load-side sensor circuitry 324 comprises current detection circuitry to sense a magnitude of load current at node N2. In this regard, the sensor circuitry 324 can be utilized by the controller 321 to detect fault conditions, e.g., overcurrent, short circuit, etc., and allow the controller 321 to generate switch control signal S_Con to deactivate the solid-state AC switch 310 in the event that a fault condition is detected. In some embodiments, the intelligent solid-state circuit breaker 300 is implemented using exemplary circuit breaker architectures and techniques as disclosed in U.S. Pat. No. 11,373,831, which is commonly assigned and fully incorporated herein by reference.

As schematically illustrated in FIG. 3, the solid-state AC switch 310 is connected between the line side node N1 and the load side node N2 in an electrical path between the first power input terminal 300-1 and the first load terminal 300-3. As noted above, in some embodiments, the solid-state AC switch 310 comprises a bidirectional solid-state switch device which comprises two serially connected solid-state switches with a common node connection. For example, FIG. 4 schematically illustrates an embodiment of a solid-state AC switch, which can be implemented in the intelligent solid-state circuit breaker 300 of FIG. 3, according to an exemplary embodiment of the disclosure.

More specifically, FIG. 4 schematically illustrates a bidirectional solid-state switch 400 which comprises a first solid-state switch 401 and a second solid-state switch 402, which are serially connected between the first node N1 and the second node N2, and which are coupled back-to-back at node N4. In some embodiments, the two solid-state switch devices 113 as shown in FIGS. 1A and 2B, comprise the first solid-state switch 401 and the second solid-state switch 402. In some embodiments, the bidirectional solid-state switch 400 comprises a bidirectional MOSFET switch in which the first and second solid-state switches 401 and 402 comprise power MOSFET devices, e.g., N-type enhancement MOSFET devices, having respective gate terminals (G), drain terminals (D), and source terminals(S). The drain terminal (D) of the first solid-state switch 401 is coupled to the line side node N1, and the drain terminal (D) of the second solid-state switch 402 is coupled to the load side node N2. The source terminals(S) of the first and second solid-state switches 401 and 402 are commonly coupled at the common node N4, thereby implementing a common source bidirectional MOSFET switch configuration. The gate terminals (G) of the first and second solid-state switches 401 and 402 are commonly connected to node N5 through the respective resistors 410 and 411.

As further shown in FIG. 4, the first and second solid-state switches 401 and 402 comprise intrinsic body diodes 401-1 and 402-1, respectively, wherein each intrinsic body diode 401-1 and 402-1 represents a P-N junction between a P-type substrate body and an N-doped drain region of the respective N-type MOSFET device. It is to be noted that intrinsic body-to-source diodes of the first and second solid-state switches 401 and 402 are not shown as such intrinsic body-to-source diodes are assumed to be shorted out by a common connection between the source terminal(S) and a body terminal (e.g., the N-source region and P-doped body junction are shorted through source metallization).

While FIG. 4 illustrates an exemplary embodiment in which the bidirectional solid-state switch 400 comprises two MOSFET devices, e.g., the first and second solid-state switches 401 and 402, in some embodiments, as explained in further detail in conjunction with FIG. 5, each of the first and second solid-state switches 401 and 402 can be implemented with two or more MOSFET devices connected in parallel, with a configuration that enables enhanced heat dissipation and enhanced power handling. Furthermore, in some embodiments, the bidirectional solid-state switch 400 can be implemented using other types of solid-state switch devices. For example, in some embodiments, the first and second solid-state switches 401 and 402 are implemented using integrated gate bipolar transistor (IGBT) devices having emitter terminals that are commonly connected at the common node N4. In other embodiments, the first and second solid-state switches 401 and 402 can be implemented using other types of FET devices including, but not limited to, GaN (Gallium Nitride) FET devices, cascode GaN FET devices, silicon carbide (SiC) junction FET devices, cascode SiC junction FET devices, etc.

In all embodiments, the bidirectional solid-state switch 400 is configured to (i) allow the bidirectional flow of AC current in the electrical path between the nodes N1 and N2 when the bidirectional solid-state switch 400 is in a turned-on state and (ii) interrupt the bidirectional flow of AC current in the electrical path between nodes N1 and N2 when the bidirectional solid-state switch 400 is in a turned-off state. As noted above, the bidirectional solid-state switch 400 can be turned on and off by applying appropriate gate control signals G_Con to the gate (G) terminals of the first and second solid-state switches 401 and 402, which are commonly coupled to node N5.

FIG. 5 schematically illustrates an embodiment of a solid-state AC switch, which can be implemented in a solid-state circuit breaker, according to an exemplary embodiment of the disclosure. In particular, FIG. 5 schematically illustrates a solid-state AC switch 500 which comprises a plurality of bidirectional solid-state switches 510, 520, and 530, connected in parallel between the nodes N1 and N2. For ease of illustration, the gate control line(s) are not shown in FIG. 5. The bidirectional solid-state switch 510 comprises a first solid-state switch 511 and a second solid-state switch 512 serially connected back-to-back between nodes N1 and N2. The bidirectional solid-state switch 520 comprises a first solid-state switch 521 and a second solid-state switch 522 serially connected back-to-back between nodes N1 and N2. The bidirectional solid-state switch 530 comprises a first solid-state switch 531 and a second solid-state switch 532 serially connected back-to-back between nodes N1 and N2. The exemplary configuration of the solid-state AC switch 500 enables enhanced heat dissipation and enhanced power handling for, e.g., a circuit breaker with a high current rating (e.g., 20 A or more). It is to be noted that FIG. 5 illustrates an exemplary configuration in which the first substrate 111 as shown in FIGS. 1A and 2B, for example, would comprise six (6) solid-state switches disposed on the frontside of the first substrate 111, with the first cooling plate 121 coupled to the backside of the first substrate 111 to absorb heat generated by the six (6) solid-state switches.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A circuit breaker, comprising an integrated heat sink which is configured to absorb and dissipate heat from electronic components of the circuit breaker using a combination of conduction and convection.

2. The circuit breaker of claim 1, wherein:
the integrated heat sink is disposed within a plastic housing of the circuit breaker; and
the integrated heat sink comprises at least one extended portion which extends out from the plastic housing and is configured to dissipate heat to an external environment.

3. The circuit breaker of claim 2, wherein the at least one extended portion comprises an external cooling fin structure that is configured to dissipate heat to external ambient air through convective heat transfer.

4. The circuit breaker of claim 2, wherein the at least one extended portion comprises a rail contact structure which is configured to couple to a circuit breaker mounting rail and dissipate heat to the circuit breaker mounting rail through conductive heat transfer.

5. The circuit breaker of claim 4, wherein the circuit breaker mounting rail comprises a DIN rail mount.

6. The circuit breaker of claim 1, wherein the integrated heat sink comprises a unitary molded element formed of a thermally conductive material.

7. The circuit breaker of claim 6, wherein the integrated heat sink comprises a unitary molded aluminum structure.

8. The circuit breaker of claim 1, wherein:
the circuit breaker comprises an electronic assembly which comprises a first substrate and a second substrate;
the electronic components comprise (i) a plurality of solid-state switch devices mounted on the first substrate, and configured to implement a solid-state alternating current (AC) switch, and (ii) integrated circuit (IC) chips mounted on the second substrate, and configured to implement control circuitry for controlling operation of the solid-state AC switch;
the integrated heat sink comprises a first cooling plate and a second cooling plate;
the first and second substrates of the electronic assembly are disposed between the first and second cooling plates; and
the first and second cooling plates are configured to absorb heat, which is generated by the electronic components, through conduction.

9. The circuit breaker of claim 8, wherein:
the plurality of solid-state switch devices are mounted on a frontside surface of the first substrate;
the IC chips are mounted on a frontside surface of the second substrate;
the first cooling plate is thermally coupled to a backside surface of the first substrate, opposite the frontside surface of the first substrate; and
the second cooling plate is thermally coupled to backside surfaces of the IC chips.

10. The circuit breaker of claim 8, wherein:
the electronic assembly comprises a first wire connector terminal coupled to the first substrate, and a second wire connector terminal coupled to the first substrate;
the first and second wire connector terminals are configured to absorb heat from the first substrate through conduction, and dissipate heat to an external environment through conduction of the heat to electrical wiring connected to the first and second wire connector terminals.

11. The circuit breaker of claim 8, wherein the first and second cooling plates are configured to absorb heat generated by the electronic components and create a temperature differential between the first and second cooling plates which causes a convective air flow within a housing of the circuit breaker to circulate heated air to other components of the integrated heat sink and cause convective heat transfer from the heated air to the other components of the integrated heat sink.

12. The circuit breaker of claim 11, wherein the other components of the integrated heat sink comprise one or more cooling fin structures.

13. A circuit breaker, comprising:
an electronic assembly comprising electronic components; and
an integrated heat sink which is configured to absorb and dissipate heat from the electronic components of the electronic assembly;
wherein the integrated heat sink comprises a first cooling plate and a second cooling plate;
wherein at least a portion of the electronic assembly is disposed between the first and second cooling plates to cause the first and second cooling plates to absorb heat generated by the electronic components through conduction.

14. The circuit breaker of claim 13, wherein the first and second cooling plates are configured to absorb heat generated by the electronic components and create a temperature differential between the first and second cooling plates which causes a convective air flow within a housing of the circuit breaker to circulate heated air to other components of the integrated heat sink and cause convective heat transfer from the heated air to the other components of the integrated heat sink.

15. The circuit breaker of claim 13, wherein the other components of the integrated heat sink comprise one or more cooling fin structures.

16. The circuit breaker of claim 13, wherein:
the electronic assembly comprises a first wire connector terminal and a second wire connector terminal;
the first and second wire connector terminals are configured to absorb heat through conduction, and dissipate the heat to an external environment through conduction of the heat to electrical wiring connected to the first and second wire connector terminals.

17. The circuit breaker of claim 13, wherein:
the integrated heat sink comprises at least one extended portion which extends out from a plastic housing of the circuit breaker and configured to dissipate heat to an external environment.

18. The circuit breaker of claim 17, wherein the at least one extended portion of the integrated heat sink comprises:
a rail contact structure which is configured to couple to a circuit breaker mounting rail and dissipate heat to the circuit breaker mounting rail through conductive heat transfer; and
an external cooling fin structure that is configured to dissipate heat to external ambient air through convective heat transfer;
wherein the external cooling fin structure is further configured as a fixed clip mechanism to secure the circuit breaker to mounting rail in conjunction with a plastic clip of the plastic housing.

19. A DIN rail mount circuit breaker, comprising an integrated heat sink which is configured to absorb and dissipate heat from electronic components of the DIN rail mount circuit breaker, wherein the integrated heat sink comprises a first extended portion which extends out from a plastic housing of the DIN rail mount circuit breaker and which is configured make thermal contact to a DIN rail mount to dissipate heat from the integrated heat sink to the DIN rail mount.

20. The DIN rail mount circuit breaker of claim 19, wherein the integrated heat sink further comprises a second extended portion which is (i) configured to dissipate heat to external ambient air through convective heat transfer, and (ii) configured to operate as fixed clip mechanism to secure the DIN rail mount circuit breaker to the DIN rail mount in conjunction with a plastic clip of the plastic housing.
